(19) United States
(12) Patent Application Publication
(10) Pub. No.: US 2025/0123349 A1
(43) Pub. Date: Apr. 17, 2025

(54) MULTIPORT RF CALIBRATION USING PEER-TERMINATED STANDARDS

(71) Applicant: MPI Corporation, Hsinchu County (TW)

(72) Inventors: Kooho Jung, Hsinchu County (TW); Hung-Che Fu, Hsinchu County (TW)

(73) Assignee: MPI Corporation, Hsinchu County (TW)

(21) Appl. No.: 18/820,228

(22) Filed: Aug. 29, 2024

Related U.S. Application Data
(60) Provisional application No. 63/543,957, filed on Oct. 13, 2023.

(51) Int. Cl. G01R 35/00

(52) U.S. Cl. CPC G01R 35/005

(57) ABSTRACT

A new type of calibration standards is presented, which has the uncalibrated peer-ports terminated to matching impedances such as 50Ω. Terminating peer-ports increases calibration accuracy since the calibration process is less affected by the undesired crosstalk in the error-network that is being calibrated or in the calibration standards themselves. Using the disclosed peer-terminated standards were shown to have less calibration errors over using conventional dual standards. This is applicable to any electrical measurement and calibration, where the calibration standards are designed to simultaneously connect multiple ports.

### CROSS-REFERENCE TO RELATED PATENT APPLICATION

This application claims the benefit of priority to the U.S. Provisional Patent Application Ser. No. 63/543,957, filed on Oct. 13, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a device, a system and a method, and more particularly to multiport RF measurement and calibration.

### BACKGROUND OF THE DISCLOSURE

With the advancement of network analyzer technology, RF measurement and calibration method have been consistently enhanced and refined. However, most conventional calibration method assumes mutually isolated RF channels in the error-network that is being calibrated and in the calibration standards themselves. Hence, any crosstalk in the error-network or in the standards can cause calibration errors which will be manifested as measurement errors. This becomes especially challenging when using RF probes to measure wafer, integrated circuit (IC), or printed circuit board (PCB), where the calibration standards are designed to simultaneously connect multiple ports.

### SUMMARY OF THE DISCLOSURE

In order to solve the above-mentioned problem, a new type of RF calibration standards is presented, which has the uncalibrated peer-ports terminated to matching impedances such as 50Ω. Terminating peer-ports increases calibration accuracy since the process is less affected by the undesired crosstalk (XT) in the error-network that is being calibrated or in the calibration standards themselves. This is due to:
reduced reflections of RF signals that had propagated to peer-ports caused by undesired XT;
reduced XT in long thru/line standards by avoiding long parallel transmission lines as in the conventional dual standards;
consistent RF channels in the error-network with less unintentional mutual coupling to other RF channels; and
having similar environments between calibration and measurement when the ports are terminated to matching impedances such as 50Ω.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of general multiport (N-port) RF measurement;

FIG. 2 is a schematic diagram of 4-port RF measurement using 2 dual wafer probes;

FIG. 3 is a schematic diagram of conventional dual standards for calibrating 4-port RF measurement using 2 dual wafer probes;

FIG. 4 is an illustration of crosstalk (XT) among selected channels mentioned in FIG. 2 and in selected standards mentioned in FIG. 3 in terms of non-zero s-parameters;

FIG. 5 is an illustration of RF channels' XT caused inconsistency during calibration when measuring short, open, load standards;

FIG. 6 is an illustration of RF channels' XT caused mutual coupling during calibration when measuring various through (thru) standards;

FIG. 7 is an illustration that compares schematics between conventional dual standards and the disclosed peer-terminated standards;

FIG. 8 is an illustration of RF channels' consistency achieved by using peer-terminated standards;

FIG. 9 is an illustration of RF channels' reduced mutual coupling achieved by using peer-terminated standards;

FIG. 10 compares open/short tests results of a multi-line thru-reflect-line (mTRL) calibration using conventional dual standards and the disclosed peer-terminated standards;

FIG. 11 compares open/short tests results of a short-open-load reciprocal-thru (SOLR) calibration using conventional dual standards and the disclosed peer-terminated standards;

FIG. 12 is a schematic diagram of N-port peer-terminated short standards;

FIG. 13 is a schematic diagram of N-port peer-terminated open standards;

FIG. 14 is a schematic diagram of N-port peer-terminated load standard; and

FIG. 15 is a schematic diagram of N-port peer-terminated thru/line standards.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

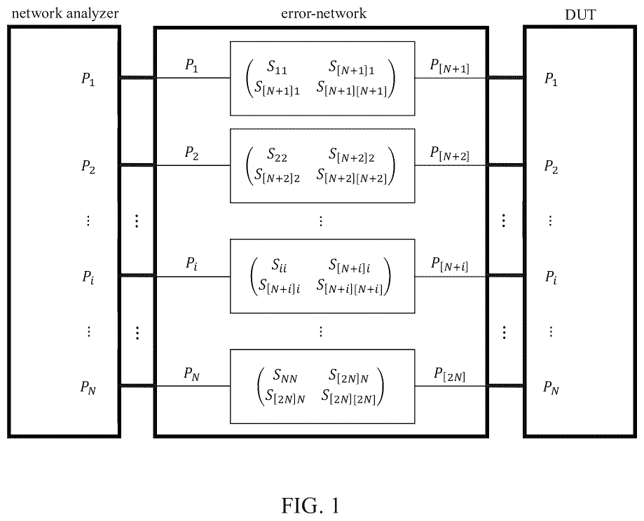

A Schematic diagram of general multiport (N-port) RF measurement is shown in FIG. 1. Although the same notation for ports (Pᵢ) are used for each part, their physical ports are obviously different, which will be distinguished by the used context. For clarity, the used terms in are defined as follows:

“error-network” is the 2N-port network that models everything between device under test (DUT) and the ideal interfaces of the network-analyzer that causes measurement errors (e.g. cables, connectors, probes, network analyzer's none-idealities);

“channel” is a 2-port network that represents parts of error-network for each measurement ports (e.g. network between Pᵢ and P_{[N+i]}) as illustrated by the annotated 2×2 s-parameter matrices;

“calibration” is the mathematical operation that deletes the effects of the error-network from raw measurements; and

“error-terms” is error-network's s-parameters (and their products) that are required to define the error-network.

For simplicity, this disclosure had assumed that the error-network is reciprocal (i.e. S_{[N+i]i}=S_{i[N+i]}) which is very common. However, the disclosed invention can be applied regardless of such reciprocity.

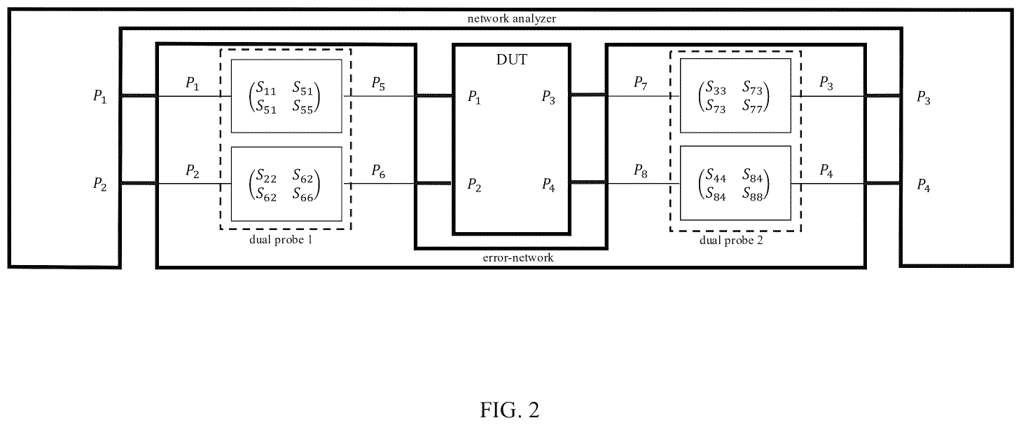

A schematic diagram of 4-port RF measurement using 2 dual wafer probes is shown in FIG. 2. The left section of the error-network (connected to P₁, P₂, P₅, P₆) represents the dual probe measuring from the left, while those on the right (connected to P₃, P₄, P₇, P₈) represents the dual probe measuring from the right. The needed error-terms to calibrate this error-network are in terms of the s-parameters shown in the 2×2 s-parameter matrices at each channel.

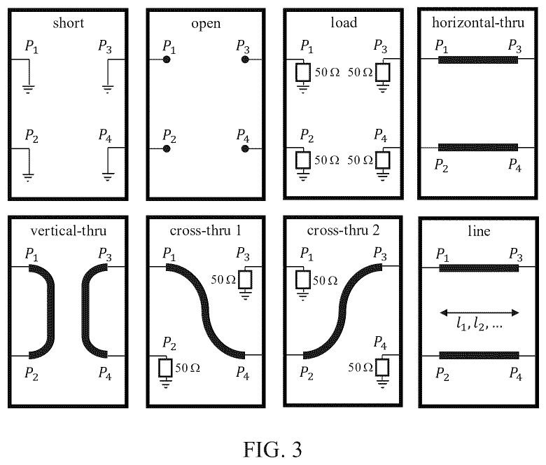

The error-terms are calculated by measuring the conventional dual standards as shown in FIG. 3. They are calculated by measuring some or all of these standards, where the ones that are measured varies per used calibration method.

The short, open, load standards do not have to be ideal, but their parasitic parameters may need to be known per used calibration method. Some of these standards may require symmetry among selected ports per used calibration method. The thick lines in the various through (thru) and line standards represent RF transmission line (TL). These TLs do not have to be ideal, but their characteristic impedances or propagation delays may need to be known per used calibration method. Some of these standards may require symmetry among selected ports per used calibration method. Note that line standards are usually made identical to the horizontal-thru standard except they come in various lengths as illustrated by l₁, l₂. Other calibration standards (not shown in FIG. 3) may be used for advanced or specialized calibration methods.

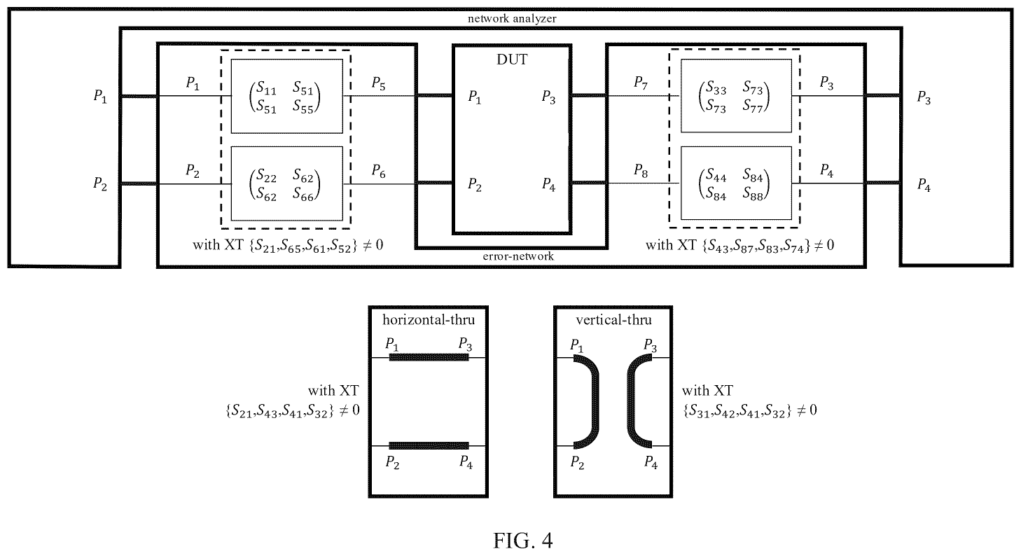

Most calibration methods assume perfect isolation among the channels in the error-network and among the ports of the calibration standards except for those connected by TLs in thru/line standards. However, this is often not the case due to various crosstalk (XT) among channels and among ports in thru/line standards as illustrated by non-zero s-parameters in FIG. 4. The presence of such XT can cause calibration errors at various steps in the calibration process as will be shown in this disclosure. Note, more XT often exists for line standards not shown in this figure.

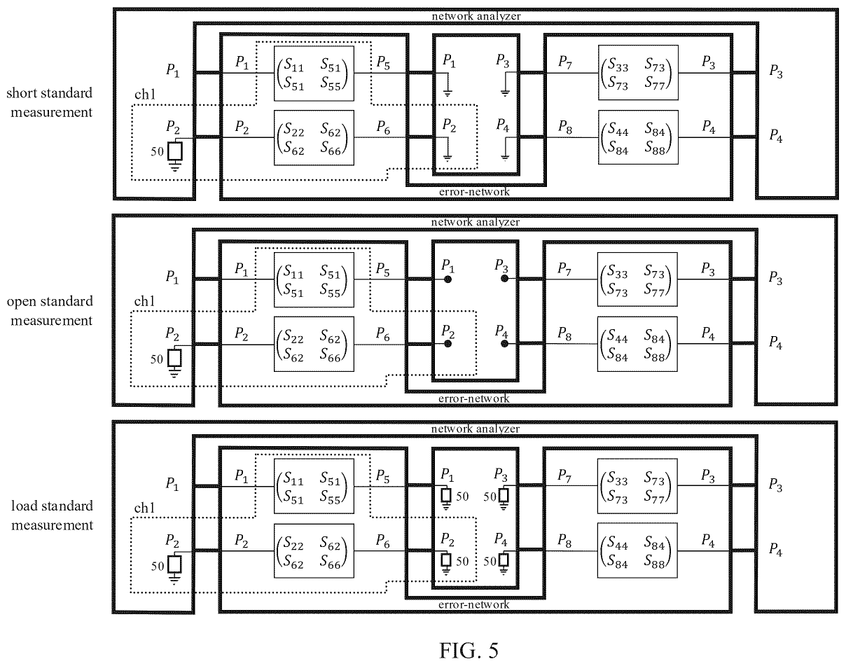

FIG. 5 is an illustration of RF channels' XT caused inconsistency during calibration when measuring short, open, load standards. Port-1's channel (between P₁ and P₅ in the error-network) is shown by the enclosed dotted-lines labeled as “ch1”. Since, ch1 is extended to port-2's channel (between P₂ and P₆ in the error-network) due to XT, it changes per each standard as shown by the varying connections at standards' P₂. Such inconsistency causes error in the extracted error-terms. The same applies to all other channels.

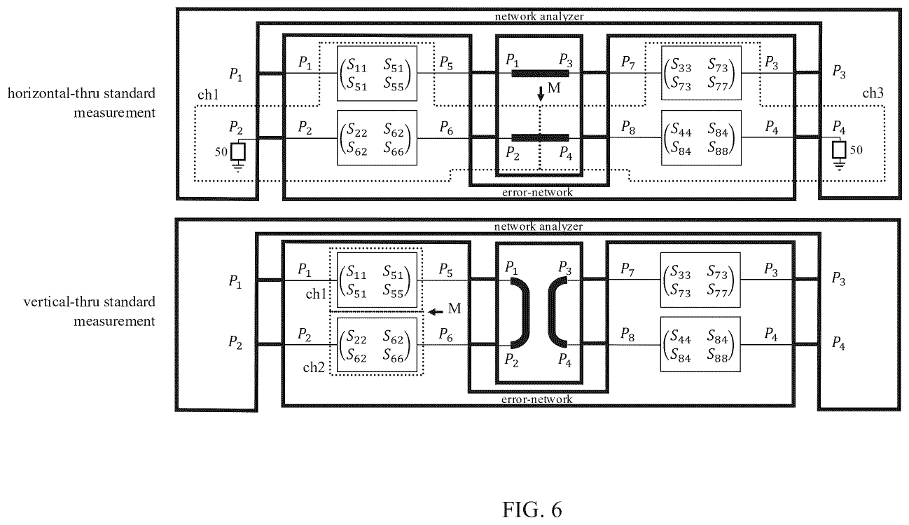

FIG. 6 is an illustration of RF channels' XT caused mutual coupling during calibration when measuring various thru standards.

In measuring horizontal-thru, port-1's channel (between P₁ and P₅ in the error-network) and port-3's channel (between P₃ and P₇ in the error-network) are shown by the enclosed dotted-lines labeled as “ch1” and “ch3”, respectively. These channels are coupled through the mutual boundary labeled as “M”, and further coupled to other channels if there is XT between two TLs in the horizontal-thru standard. Such mutual coupling causes error in the extracted error-terms. The same applies to all other channels, and also when measuring line standards not shown in this figure.

In measuring vertical-thru, port-1's channel (between P₁ and P₅ in the error-network) and port-2's channel (between P₂ and P₆ in the error-network) are shown by enclosed dotted-lines labeled as “ch1” and “ch2”, respectively. These channels are coupled through the mutual boundary labeled as “M”, and further coupled to other channels if there is XT between two TLs in the vertical-thru standard. Such mutual coupling causes error in the extracted error-terms. The same applies to all other channels.

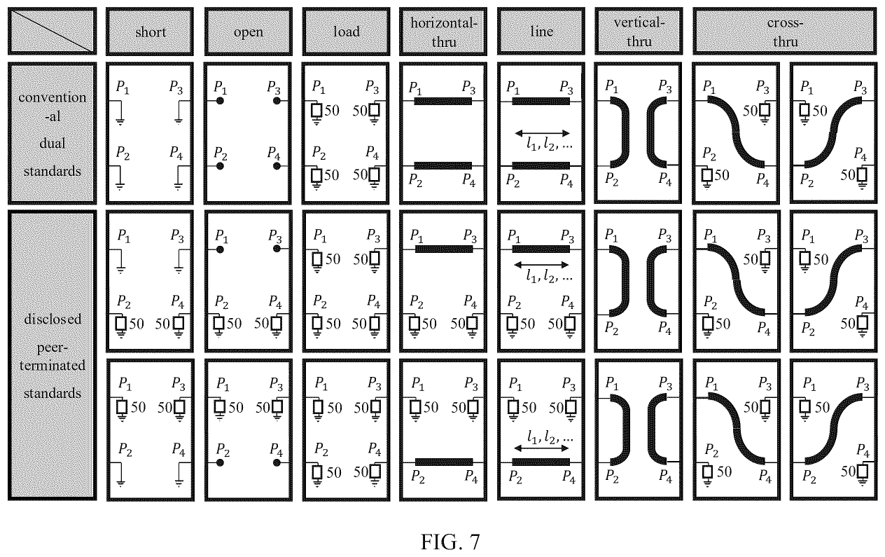

In order to solve such XT problems, a new type of RF calibration standards is presented, which has the XT sensitive peer-ports terminated to matching impedance (50Ω) as shown in FIG. 7 along with the conventional dual standards for comparison. The used circuit elements, notations, and various characteristics are same as those mentioned in FIG. 3, except the “50Ω” is simply shown as “50”. Note that the vertical-thru are made identical to that of the conventional dual standards, since the XT between the left-side and right-side of the error-network (between left and right probe) is assumed to be low. Also note that the cross-thru are made identical to those of the conventional dual standards, since the peer-ports are already terminated to 50Ω.

Calibration accuracy is increased by terminating peer-ports, due to:
reduced reflections of RF signals that had propagated to peer-ports caused by XT;
reduced XT in long thru/line standards by avoiding long parallel TL as in the conventional dual standards; and
consistent channels in the error-network with less unintentional mutual coupling to other channels.

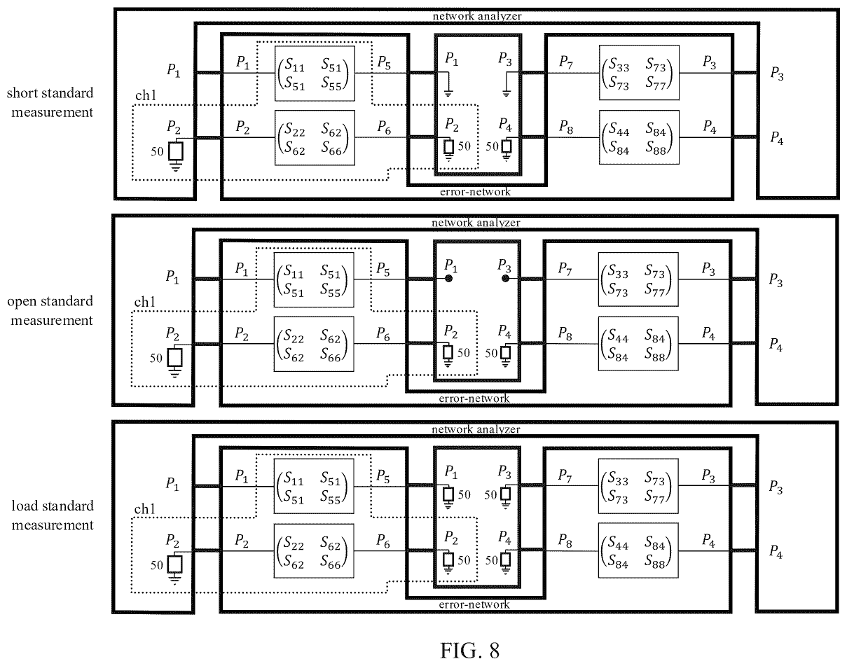

Channels' consistency when using peer-terminated standards is shown in FIG. 8. Port-1's channel (between P₁ and P₅ in the error-network) is shown by the enclosed dotted-lines labeled as “ch1”. Although, ch1 is extended to port-2's channel (between P₂ and P₆ in the error-network) due to XT, it remains consistent since standards' P₂ in is always terminated to 50Ω. Such consistency applies to all other channels.

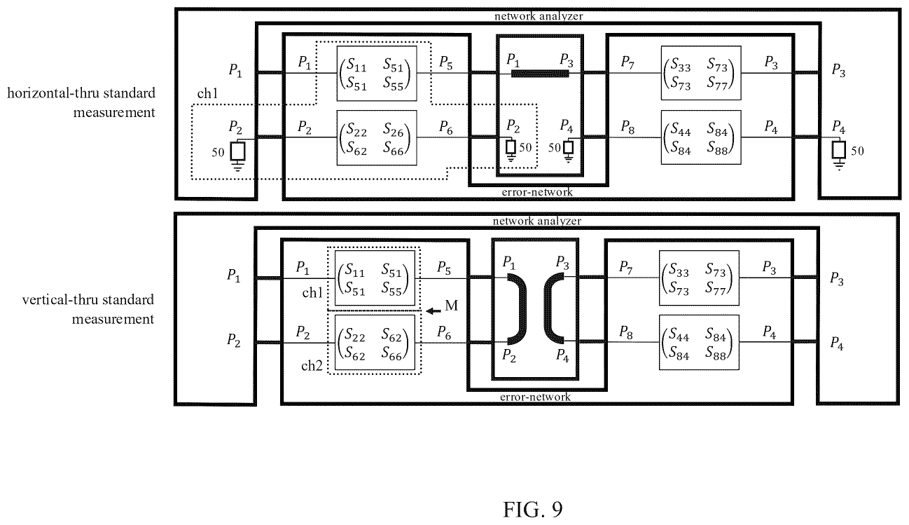

Channels' reduced mutual coupling when using peer-terminated standards is shown in FIG. 9.

In the horizontal-thru standard measurement, port-1's channel (between P₁ and P₅ in the error-network) is shown by the enclosed dotted-lines labeled as “ch1”. This ch1 is not coupled to other channels and it is consistent with measuring short, open, or load standards. The same applies to all other channels, and also when measuring line standards not shown in this figure.

The vertical-thru standard is the same as that of the conventional dual standards, so it has the same mutual coupling problem between port-1's channel (between P₁ and P₅ in the error-network) labeled as “ch1” and port-2's channel (between P₂ and P₆ in the error-network) labeled as “ch2” through the boundary labeled as “M”, which causes error in the extracted error-terms. However, their effects can be minimized or eliminated by some calibration methods such as short-open-load reciprocal-thru (SOLR) calibration where the vertical-thru measurement is only used to extract relative signs between S₅₁ and S₆₂ and relative signs between S₇₃ and S₈₄, while using amplitudes extracted from short, open, load measurements. This was also the case when using conventional dual standards, but would have used inaccurate amplitudes due to mentioned inconsistent channels. The same applies to all other channels.

Furthermore, if the DUT are designed to operate under matched condition as in most cases, using such peer-terminated standards further increases calibration accuracy for having similar environments between calibration and measurement.

Resulting calibration errors when using the disclosed peer-terminated standards is compared with that of the conventional dual standards. Two calibration methods were processed; multi-line thru-reflect-line (mTRL) calibration and the previously mentioned SOLR calibration, which are both commonly used in RF measurements. These calibrations are applied to known error-network and calibration standards that are modeled using circuit elements. Error-network was modeled with XT and various parasitic values that are in the same order of magnitudes as those of commercially available dual probes. Calibration standards were modeled using calibration-coefficients whose values that are in the same order of magnitudes as those of commercially available calibration standards.

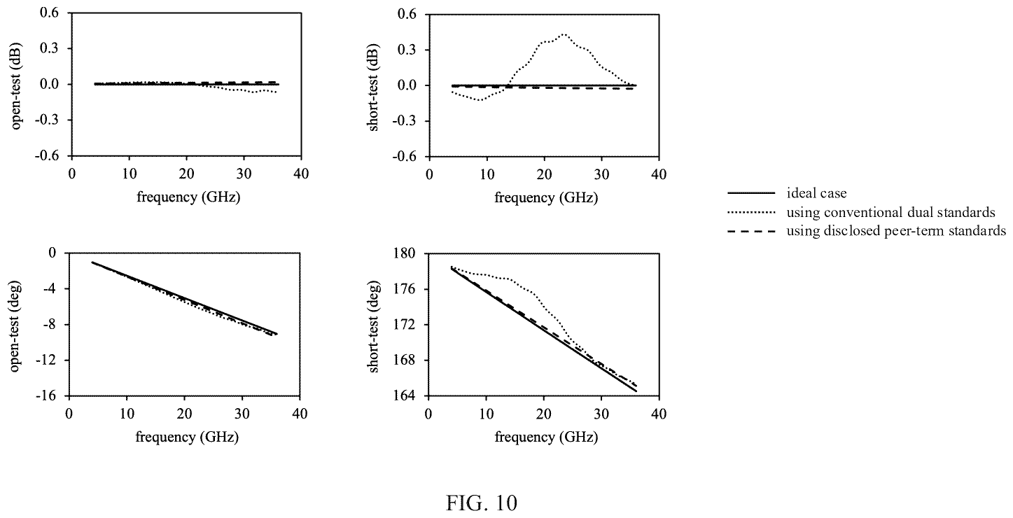

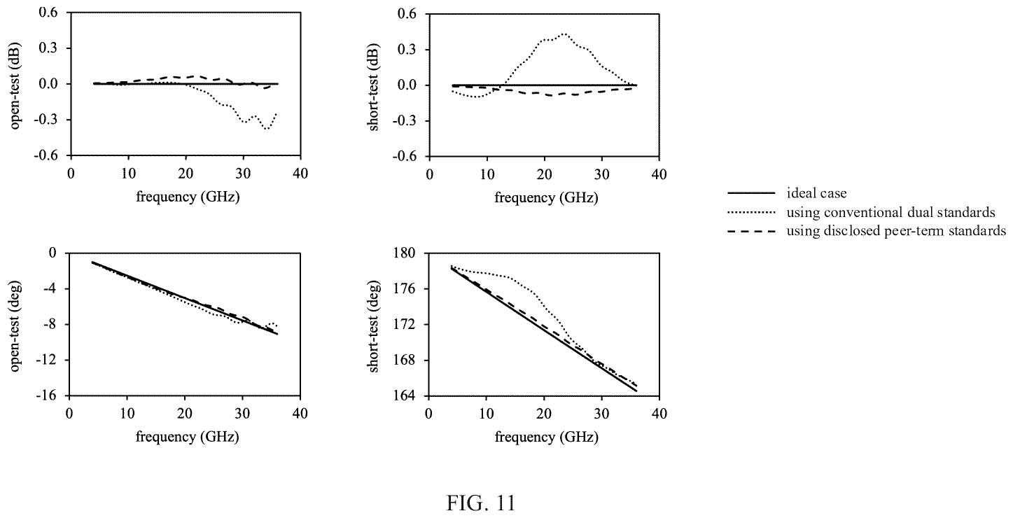

Comparison results are shown in FIG. 10 for mTRL calibration and in FIG. 11 for SOLR calibration. They are compared using post-calibration open/short tests which are commonly used to in RF measurements, where one can assess calibration error by the amount of deviation from the ideal case (solid lines). For both mTRL and SOLR calibrations, using peer-terminated standards (dashed lines) shows less calibration error over the conventional dual standards (dotted lines); up to 0.4 dB less in magnitude and up to 3 deg less in phase. Such improvement is quite significant considering that the open/short test boundaries of a decent calibration are usually less than 0.4 dB at frequencies up to 40 GHz.

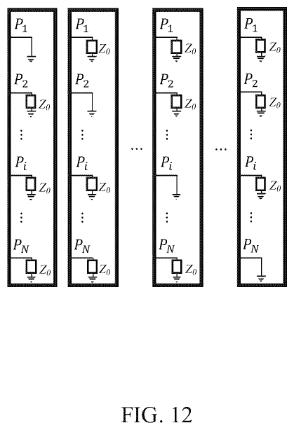

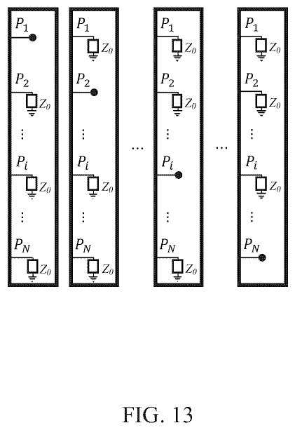

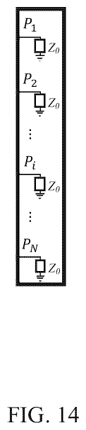

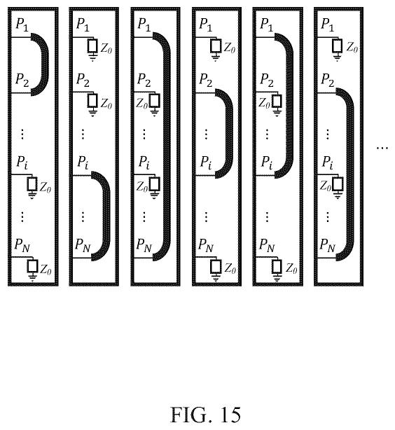

Peer-terminated standards can be used in calibrating general multiport (N-port) by using N-port peer-terminated standards for short, open, load, thru/line as shown in FIG. 12, FIG. 13, FIG. 14, FIG. 15, respectively. The used circuit elements, notations, and various characteristics are same as those mentioned in FIG. 3, except the “50Ω” is replaced by general impedance “Z₀”. These N-port peer-terminated standards can be applied to any measurements whose varieties may include number of ports (>1), type of calibration interface (e.g. IC, PCB), terminated impedance (e.g. 50Ω, 100Ω), signal's shape (e.g. sinusoidal-waves, rectangular-waves), frequency band (e.g. analog, RF, optical band), mode (e.g. single-ended, differential-mode, common-mode), and measured metric (e.g. S-parameters, eye-diagram). In general, peer-terminated standards can be applied to any electrical measurements where that calibration standards are designed to simultaneously connect multiple ports, by which calibration accuracy can be increased due to reduced effects of undesired electrical crosstalk in an error-network or in the calibration standard itself.

What is claimed is:

1. A calibration standard for electrical measurements that simultaneously connects to multiple ports comprising:
measured-ports that are connected to electrical elements where their electrical characteristics are fully or partially known;
crosstalk-sensitive peer-ports that are terminated to matching impedances or nearby values;
wherein a calibration accuracy is increased by reduced effects of undesired electrical crosstalk in an error-network or in the calibration standard itself;
the term “error-network” is a modeled network that causes measurement errors that exists between a device under test (DUT) and ideal interfaces of measurement equipment;
the term “calibration” is a mathematical operation that eliminates the effects of the error-network from raw measurements;
the term “measured-ports” are ports on the calibration standard from which measurements are collected and used for extracting the error-network; and
the term “crosstalk-sensitive peer-ports” are ports on the calibration standard that are electrically coupled to the measured-ports through the undesired electrical crosstalk in the error-network or in the calibration standard itself.

2. The calibration standard according to claim 1, wherein:
calibration interface is an integrated circuit (IC) or a printed circuit (PCB);
shape of applied signal is sinusoidal-waves or rectangular-waves;
applied mode is single-ended, in differential-mode, or in common-mode;
applied frequency is analog, radio frequency (RF), or optical band; and
measured metric is in frequency-domain or in time-domain.

3. The calibration standard according to claim 2, wherein:
the applied error-network includes RF probes; and
the applied DUT is an IC or PCB.

4. A calibration method, implemented by software or firmware, using the calibration standard of claim 1.

5. A calibration method, implemented by software or firmware, using the calibration standard of claim 2.

6. A calibration method, implemented by software or firmware, using the calibration standard of claim 3.
